(19) United States
(12) Patent Application Publication
(10) Pub. No.: US 2011/0193200 A1
(43) Pub. Date: Aug. 11, 2011

(54) SEMICONDUCTOR WAFER CHIP SCALE PACKAGE TEST FLOW AND DICING PROCESS

(76) Inventors: Kevin P. Lyne, Fairview, TX (US); Stanley Craig Beddingfield, McKinney, TX (US); Elida I. De Obaldia, Dallas, TX (US); Raymundo Monasterio Camenforte, Allen, TX (US); David Charles Stepniak, Dallas, TX (US)

(21) Appl. No.: 12/881,845

(22) Filed: Sep. 14, 2010

Related U.S. Application Data
(60) Provisional application No. 61/302,770, filed on Feb. 9, 2010.

(51) Int. Cl. H01L 23/544; H01L 21/66; H01L 21/304

(52) U.S. Cl. 257/622; 438/18; 438/462; 257/E21.521; 257/E21.238; 257/E23.179

(57) ABSTRACT

A method for forming a semiconductor device can include electrically testing a plurality of semiconductor dies in wafer form subsequent to performing a first wafer dicing process, then performing a second wafer dicing process to dice the wafer and to singularize the plurality of semiconductor dies. Electrically testing the plurality of semiconductor dies in wafer form subsequent to the first dicing process can identify chips damaged during the first dicing process. The method can also include forming a plurality of grooves between adjacent dies which leaves a full wafer thickness at a perimeter of the wafer to result in a wafer which is more resistant to deflection and damage during handling.

### PRIORITY

This application claims priority to U.S. Provisional Application 61/302,770 filed Feb. 9, 2010, which is incorporated herein by reference.

### FIELD OF THE INVENTION

The present teachings relate to the field of semiconductor device manufacture, and more particularly to methods for testing semiconductor devices and dicing semiconductor wafers.

### BACKGROUND

Miniaturization of semiconductor device packages and electronic components is an ongoing goal for design engineers. Reducing a package “footprint” results in the increased availability of space on a receiving surface to which the package is mounted, such as a printed circuit board (PCB), thereby increasing the density of devices that can be attached to the receiving surface. Increasing device density is one strategy for decreasing the size of an electronic device.

A surface mount semiconductor device package includes a semiconductor die encased in a resin encapsulation material. Electrical communication with the encapsulated die can be provided through lead frame leads or a ball grid array.

To further reduce the package footprint, other device packages have been developed. For example, a wafer chip scale package (WCSP) eliminates device encapsulation altogether, and provides an unencapsulated (i.e. “bare”) die that can be mounted onto the receiving surface. This package has a very small outline that can equal the size of the die itself.

During the manufacture of WCSP devices in wafer form, a plurality of semiconductor dies (i.e. chips) are formed en masse on and within a semiconductor substrate, then the wafer is diced using a laser and/or a dicing saw. Prior to dicing the wafer, the devices can be tested, for example using a probe step. After any such testing, the semiconductor chips are then separated from each other through wafer dicing.

Wafer dicing can be performed using various methods. In a first method for dicing the wafer, the wafer is attached to a wafer frame with a thin adhesive sheet. A dicing saw, which includes a first wide, circular rotating blade, saws partially into the semiconductor substrate to form a plurality of grooves between adjacent dies in a row (or column) direction. The orientation of the wafer is rotated 90° relative to the saw blade, then the wide saw blade saws partially into the semiconductor to form a plurality of grooves in a column (or row) direction. Subsequently, a second narrow, circular blade saws completely through the wafer within the wide grooves along the rows and columns to separate dies from adjacent dies. During separation of each row and column, the wafer saw passes over the wafer twice for each row and twice for each column. Using a wide blade to form a first groove partially into the semiconductor substrate and then a narrow blade to complete the dicing process minimizes damage to the semiconductor substrate during the dicing of the wafer.

While the dicing process minimizes damage to the semiconductor substrate, the saw can damage layers overlying the semiconductor wafer. To minimize damage, a second method for dicing the wafer can include the use of a laser and two saw blades. The laser is used to ablate one or more layers overlying the semiconductor substrate such as metallization and/or dielectric, and may also ablate a portion of the semiconductor substrate. Subsequently, a first saw blade having a first width cuts or scores a wide groove partially into the semiconductor substrate along each row and column between the dies. Next, a second saw blade having a second, narrower width than the first blade cuts completely through the semiconductor substrate and partially into the adhesive film to complete the separation of the individual dies from each other along the row and column direction. Using a laser and two saw blades of two different widths reduces cracking of the brittle wafer and decreases damage to the dies.

After dicing the wafer, the chips can be assembled as part of an electronic device or packaged for shipment and delivered to a customer. Because the WCSP dies are not encapsulated, they are particularly prone to damage through contact during handling. To minimize handling and damage to the bare chips, WCSP dies may be visually inspected but are not tested electrically subsequent to dicing of the wafer.

### SUMMARY OF THE EMBODIMENTS

In one standard process flow, after an initial probe of the wafer, semiconductor wafer dicing is completed but subsequent electrical testing on the bare chips is not performed prior to use or shipment so that damage from handling is minimized. However, even a process which uses a laser and multiple passes of a dicing saw during WCSP wafer dicing can result in damage to the wafer. The potential for mounting a damaged chip to a receiving surface such as a PCB or sending a damaged chip to a customer is a possibility and costly, as the damaged die must be removed from the surface and replaced with a functional chip. Shipping damaged chips to customers or using them in a manufacturer's electronic device reduces the perception of quality of a manufacturer's part, decreasing customer loyalty, and increasing costs to the manufacturer and customer.

The inventors have therefore developed a process for testing WCSP chips after an initial wafer cut to form a groove in the wafer but prior to complete dicing of the wafer. The initial wafer cut which forms the groove can include laser ablation of layers such as metallization and dielectric between each of the dies or the semiconductor substrate itself, one or more passes of a dicing saw, or both laser ablation and one or more passes of a dicing saw prior to complete dicing of the wafer which singularizes each die. A probe process, for example, can be used to electrically test each die subsequent to forming the groove but before complete wafer dicing, or after laser ablation and one or more passes with a wafer saw blade which forms the groove in semiconductor wafer, but prior to completing the dicing process. Using the process of the present teachings, testing for damage after groove formation but prior to complete dicing can be performed to identify chips damaged during groove formation. Damage is most likely to occur during formation of the groove in layers which overlie the semiconductor substrate, as these layers predominantly form the active circuitry. The non-active silicon substrate sawn in subsequent saw passes is less sensitive to damage. Thus performing an electrical test after the first saw/groove operation can identify damaged dies. Additional sawing into the silicon substrate beneath the active layers after the first saw/groove operation is less likely to damage the active circuits.

In another aspect of the present teachings, the inventors have realized that the semiconductor wafer is particularly fragile subsequent to groove formation and prior to complete dicing. During the initial cut, the wafer is thinned at the groove such that any deflection of the wafer can result in the wafer cracking along one of the grooves. The initial grooves that run to the edge of the wafer can form fine cracks at the edge of the wafer and act as stress concentrators, thus making the wafer fragile and more prone to breakage. In contemplating ways to make the wafer more resistant to premature chip separation or damage from deflection of the wafer, the inventors have realized that conventional processes score the wafer across the entire wafer surface. To strengthen the scored wafer, the inventors have further realized that leaving the perimeter of the wafer intact would result in a wafer having increased resistance to deflection. That is, the groove can omitted at the edges of the wafer such that the wafer has its full thickness around the perimeter of the wafer subsequent to completing grooves between each of the dies along all rows and columns. Thus in this aspect, during the formation of the groove, only the center portion of the wafer which includes the dies is cut, and the perimeter of the wafer remains uncut.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is a plan view of a semiconductor wafer;

FIG. 2 is a magnified cross section along 2-2 of FIG. 1;

FIG. 3 is a magnified view of detail of the FIG. 2 structure;

FIGS. 4-6 are cross sections depicting intermediate structures that can result from an embodiment of the present teachings;

FIG. 7 is a plan view of the FIG. 1 semiconductor wafer after forming grooves;

FIGS. 8 and 9 are cross sections depicting a process for forming grooves within a wafer layer across only a portion of the wafer surface;

FIG. 10 is a cross section depicting a process for forming grooves within a semiconductor substrate across only a portion of the substrate surface; and

FIG. 11 is a flow chart depicting one embodiment of the present teachings.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to the present exemplary embodiments of the present teachings, examples of which are illustrated in the accompanying drawings. Wherever possible, the same reference numbers will be used throughout the drawings to refer to the same or like parts.

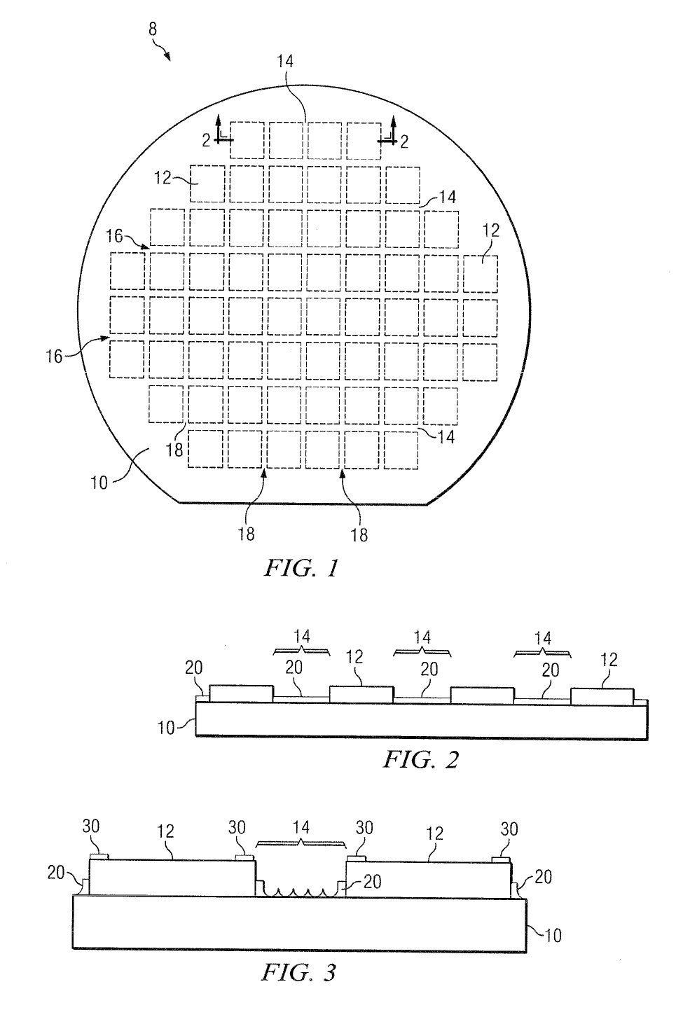

FIG. 1 depicts a semiconductor wafer 8 including a semiconductor substrate 10 and a plurality of semiconductor dies (i.e. chips) 12 that have been formed on and within the semiconductor substrate 10 using known techniques. The wafer further includes a plurality of spaces 14 arranged in rows 16 and columns 18 which separate each die from an adjacent die. The semiconductor dies 12 can include a plurality of wafer chip scale package (WCSP) chips, although the present teachings are not limited to WCSP chips.

FIG. 2 depicts a magnified view of the FIG. 1 wafer along cross section 2-2 of FIG. 1. The FIG. 2 wafer can include semiconductor substrate 10, semiconductor chips 12, and spaces 14 between each die. In addition to the structures depicted in FIG. 1, FIG. 2 further depicts layer 20 formed as part of the wafer. Layer 20 can include, for example, one or more dielectric layers and/or one or more metallization layers; as such, while layer 20 is depicted as a single layer and referred to herein as a “layer,” it will be understood that layer 20 can include a plurality of separate layers of the same or different materials, such as metal and/or dielectric. Layer 20 can be formed during chemical vapor deposition (CVD), atomic layer deposition (ALD), thermal oxidation, sputtering, etc. which is used during production of the semiconductor chips 12.

FIG. 3 is a magnified view of a portion of the FIG. 2 structure including two semiconductor dies 12 and depicting bond pads 30 on the chips that can be formed using known techniques. As also depicted in FIG. 3, an initial dicing stage has been performed by partially removing layer 20 to form a groove between each chip 12, for example through laser ablation. Laser ablation of the layer 20 can reduce damage to the portion of this layer which overlies the semiconductor dies 12. Laser ablation of wafer layer 20 can also remove a portion of the semiconductor substrate 10 such that the groove is formed in layer 12 and the semiconductor substrate 10. Other embodiments are also contemplated, including removing layer 20 using, for example, wet or dry etching, and removing layer 20 using a saw blade during an initial cutting step of the semiconductor substrate 10.

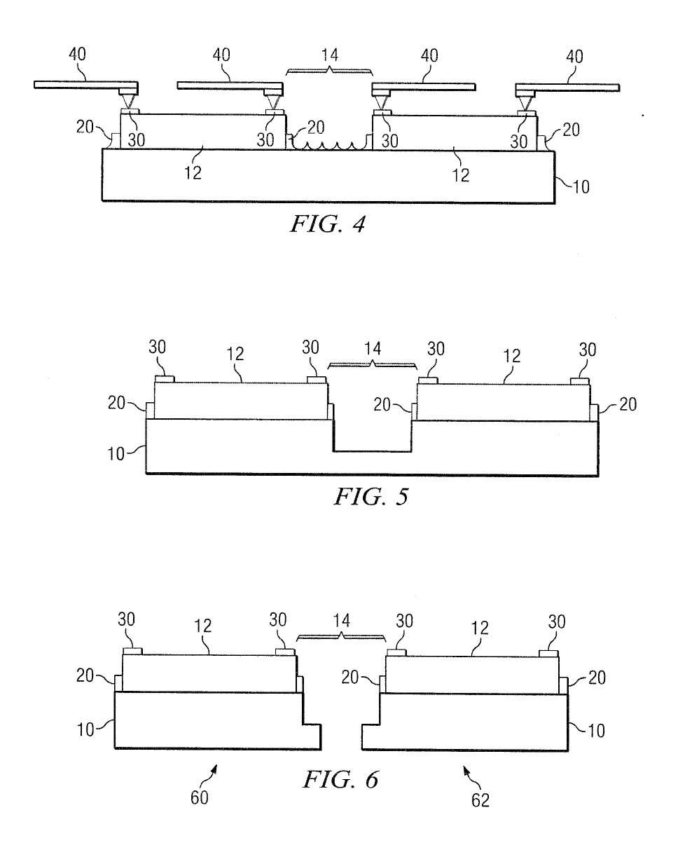

Performing laser ablation of layer 20 or cutting layer 20 using a saw blade may result in damage to the dies 12. To test for damage, an electrical test of each semiconductor die 12 can be performed, for example through the use of probe fixture that can include a plurality of probe tips 40 as depicted in FIG. 4. Each probe tip 40 is placed in electrical contact with one of the bond pads 30, then electrical testing is performed on each chip to confirm proper functionality. Any poorly functional or nonfunctional chip is noted for later scrap or rework subsequent to wafer dicing. This probe step can be performed in addition to a conventional probe step performed earlier in the manufacturing process prior to forming the groove. In another embodiment, this probe step after forming the groove can be the only probe step performed on the wafer, for example to reduce manufacturing time.

Next, as depicted in FIG. 5, a dicing stage is performed which partially cuts into the semiconductor substrate 10 along each of the spaces 14, for example using a wide saw blade, to score the wafer and extend the groove into the semiconductor wafer. Each space 14 along each row 16 and column 18 is grooved as depicted in FIG. 5. Subsequent to this dicing stage, the semiconductor dies 12 remain attached to each other through attachment with the semiconductor substrate 10.

In another embodiment of the present teachings, electrical testing of the semiconductor dies is not performed until after the semiconductor substrate 10 has been grooved as depicted in FIG. 5.

After completing the partial cut of the semiconductor substrate 10 to form the wide groove in the substrate 10, another dicing stage is performed, for example using a narrow saw blade, to separate each die from an adjacent die located across one of the spaces 14. This results in the singularized (i.e. segmented, separated) dies 60, 62 as depicted in FIG. 6.

Because the chips are electrically tested subsequent to laser ablation and/or the partial cut into the semiconductor substrate 10, any chips damaged during ablation or partial cutting are identified. Testing the chips is simplified, for example because the chips are still attached in wafer form, and individual handling of each die is not required.

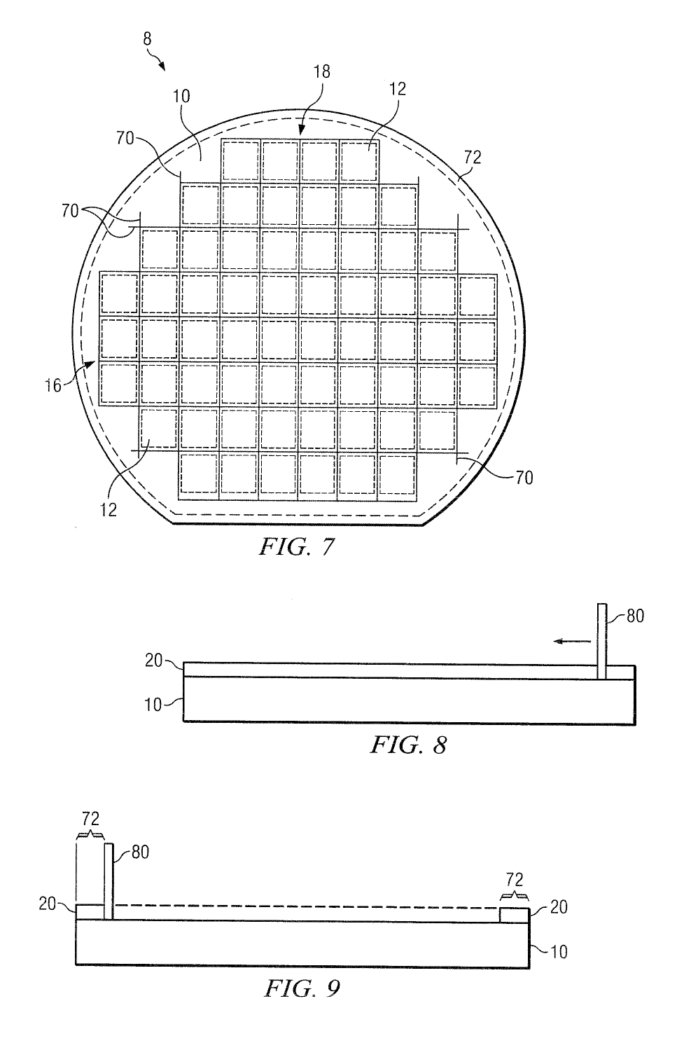

Another aspect of the present teachings is depicted in FIGS. 7-9. FIG. 7 depicts a plan view of a wafer 8 subsequent to a first dicing stage which forms grooves 70 along the spaces 14 between each die to a depth which is less than the thickness of the wafer. As depicted in FIG. 7, the grooves 70 are formed only at the central portion of the wafer 8 and are discontinued before they reach the edge of the wafer. That is, each groove terminates prior to reaching a perimeter 72 of the semiconductor wafer 8 such that the perimeter 72 remains ungrooved subsequent to forming the plurality of grooves 70. The grooves can be formed within layer 20 as depicted in FIG. 3 or within the semiconductor substrate 10 as depicted in FIG. 5, or both. Stopping the grooves prior to reaching the edge of the wafer results in a full wafer thickness at the perimeter 72 of the wafer. A wafer in accordance with this embodiment is more resistant to deflection, and thus is less likely to separate (i.e. crack) along one of the grooves 70 during electrical testing or handling prior to completing the dicing process.

FIGS. 8 and 9 depict a process for removing layer 20 at a central location of the semiconductor wafer, and leaving the full thickness of the wafer at the edges. In FIG. 8, a laser beam 80 is focused onto wafer layer 20 at a location away from the edge of the wafer. The location depicted in the FIG. 8 cross section is along one of the spaces 14 of FIG. 1. The laser beam 80 is moved across the wafer surface in the direction depicted in FIG. 8 to ablate layer 20, until it reaches the position depicted in FIG. 9, where the laser ablation is terminated. Beginning and ending the ablation away from the edges of the wafer leaves a full wafer thickness around the perimeter of the wafer, and provides for a wafer which is resistant to deflection.

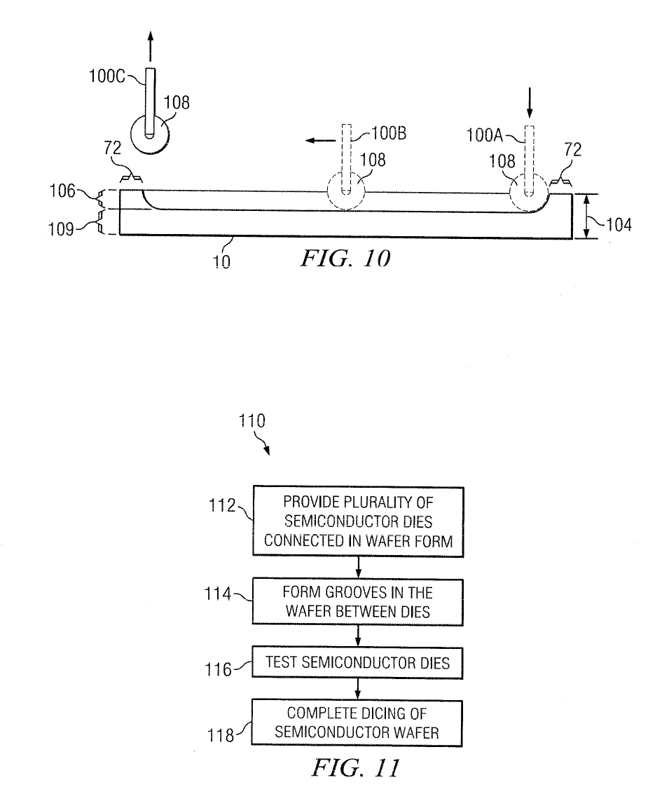

FIG. 10 depicts a process for cutting partially into the semiconductor substrate 10 using a dicing saw 100 while leaving a perimeter 72 having which is uncut. The uncut perimeter 72 has a thickness 104 which is equal to the starting thickness of the wafer. The partial cut has a depth 106 which is less than the thickness 104 of the wafer. First, a rotating saw blade 108 of the dicing saw 100A is lowered into the semiconductor substrate 10 at a location away from the edge of the semiconductor substrate. The location at which the blade 108 of dicing saw 100A is lowered into the substrate 10 can determine the width of the edge at the perimeter 72 of the semiconductor substrate 10.

After lowering the blade 108 of the dicing saw 100A into the semiconductor substrate 10, the saw blade 108 is urged across the substrate 10 within one of the spaces 14 (FIG. 1) between the dies 12 to form a groove 70 as depicted in FIG. 7. Once the dicing saw 100B reaches the opposite edge of the wafer 10, the dicing saw 100C is urged away from the semiconductor substrate 10 to remove the blade 108 from the substrate. Subsequently, the next row 14 or column 16 is similarly cut until all the grooves are formed as depicted in FIG. 7. Subsequent to forming all the grooves 70 along all the rows 14 and columns 16, the perimeter 72 of the wafer remains uncut. A thickness 104 at the edge (perimeter) of the wafer is greater than a thickness 109 of the wafer at the groove. That is, all points around the perimeter of the wafer have a thickness 104 which is greater than a thickness 109 of the wafer at the groove 70.

After forming all the grooves, either by removing layer 20 as depicted in FIGS. 8 and 9 and/or partially cutting the semiconductor substrate 10 as depicted in FIG. 10, each die is electrically tested as described above.

It will be appreciated that during formation of the grooves 70 or during complete dicing to separate the wafer into individual semiconductor chips, the laser or dicing saw can be moved relative to a stationary semiconductor wafer, the wafer can be moved relative to a stationary laser or dicing saw having a rotating blade, or both the wafer and the laser or dicing saw can be moved to complete each pass across the wafer.

FIG. 11 is a flow chart depicting a process 110 in accordance with an embodiment of the present teachings. In a first stage 112, a semiconductor wafer is provided, either through manufacture or purchase. The semiconductor wafer can include a semiconductor substrate and a plurality of semiconductor dies formed on and within the semiconductor substrate. The plurality of chips are connected together in wafer form.

In a second stage 114, an initial dicing step is performed to form grooves in the wafer. The grooves can be formed in one or more layers such as dielectric and/or metal overlying a semiconductor substrate, in the semiconductor substrate itself, or in both one or more layers and the semiconductor substrate. The grooves can be formed using one or more laser ablation passes, one or more dicing saw passes, a chemical etch, a dry etch, etc.

In a third stage 116, the semiconductor dies are electrically tested in wafer form, for example using a probe fixture or another testing technique. This testing can be performed in conjunction with prior device electrical testing, or this testing can replace conventional testing.

In a fourth stage 118, wafer dicing is completed. The wafer dicing can include one or more partial cuts to extend the depth of the groove formed at step 114 and a final cut through the wafer to complete dicing, or a single cut which completes dicing of the wafer. Dicing can be performed using a laser, a dicing saw, a wet or dry etch, or a combination of two or more of these.

Thus the present teachings can result in a semiconductor chip which has been tested subsequent to an initial dicing step. Damage resulting from the initial dicing step can be detected using electrical testing subsequent to the initial dicing step but prior to complete dicing of the wafer (i.e. prior to singularizing the semiconductor dies).

Because the formation of the grooves reduces the thickness of the wafer along grooves, the wafer can be made more resistant to deflection by forming the grooves less than all the way across the wafer. That is, subsequent to forming the grooves, the entire perimeter of the semiconductor wafer has the original thickness of the wafer.

Electrically testing the semiconductor dies subsequent to an initial dicing step can result in detection of chips which have been damaged during the initial dicing step and an increased percentage of functional devices leaving production.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method for forming a semiconductor device, comprising:
providing a semiconductor wafer comprising a plurality of semiconductor dies;
forming a groove in the semiconductor wafer between adjacent semiconductor dies, wherein the semiconductor wafer remains intact subsequent to forming the groove;
subsequent to forming the groove, electrically testing the semiconductor dies; and
subsequent to electrically testing the semiconductor dies, dicing the semiconductor wafer to form a plurality of singularized semiconductor dies.

2. The method of claim 1, wherein forming the groove comprises:
removing at least a portion of a layer overlying a semiconductor substrate.

3. The method of claim 2, wherein forming the groove comprises:
focusing a laser beam onto the layer to ablate at least a portion of the layer to form the groove in the semiconductor wafer.

4. The method of claim 1, wherein forming the groove comprises:
removing a portion of a semiconductor substrate to form the groove in the semiconductor wafer.

5. The method of claim 1, wherein electrically testing the semiconductor dies comprises:
placing a probe tip in electrical contact with a bond pad on one of the semiconductor dies.

6. A method for forming a semiconductor device, comprising:
providing a semiconductor wafer having a plurality of semiconductor dies and a perimeter;
forming a plurality of grooves within the semiconductor wafer, wherein:
each semiconductor die is separated from an adjacent die across one of the grooves; and
each groove terminates prior to reaching the perimeter of the semiconductor wafer such that the perimeter remains ungrooved subsequent to forming the plurality of grooves; and
subsequent to forming the plurality of grooves, dicing the semiconductor wafer to form a plurality of singularized semiconductor dies.

7. The method of claim 6, wherein forming the plurality of grooves comprises:
removing at least a portion of a layer overlying a semiconductor substrate.

8. The method of claim 7, wherein forming the plurality of grooves further comprises:
focusing a laser beam onto the layer to ablate at least a portion of the layer to form the plurality of grooves in the semiconductor wafer.

9. The method of claim 6, wherein forming the plurality of grooves comprises:
removing a portion of a semiconductor substrate to form the plurality of grooves in the semiconductor wafer.

10. A method for forming a semiconductor device, comprising:
providing a semiconductor wafer comprising a plurality of semiconductor dies and a perimeter;
forming a plurality of grooves in the semiconductor wafer, wherein:
each semiconductor die is separated from an adjacent die across one of the grooves;
the semiconductor wafer remains intact subsequent to forming the plurality of grooves; and
each groove terminates prior to reaching the perimeter of the semiconductor wafer such that the perimeter remains ungrooved subsequent to forming the plurality of grooves;
subsequent to forming the plurality of grooves, electrically testing the semiconductor dies; and
subsequent to electrically testing the semiconductor dies, dicing the semiconductor wafer to form a plurality of singularized semiconductor dies.

11. The method of claim 10, wherein forming the plurality of grooves comprises:
removing at least a portion of a layer overlying a semiconductor substrate.

12. The method of claim 11, wherein forming the plurality of grooves further comprises:
focusing a laser beam onto the layer to ablate at least a portion of the layer to form the plurality of grooves in the semiconductor wafer.

13. The method of claim 10, wherein forming the plurality of grooves comprises:
removing a portion of a semiconductor substrate to form the plurality of grooves in the semiconductor wafer.

14. The method of claim 10, wherein electrically testing the semiconductor dies comprises:
placing a probe tip in electrical contact with a bond pad on one of the semiconductor dies.

15. A semiconductor wafer, comprising:
a semiconductor substrate;
a plurality of grooves; and
a wafer perimeter,
wherein each of the plurality of grooves terminates prior to the wafer perimeter, such that a thickness of the wafer at the wafer perimeter is greater than a thickness of the wafer at the plurality of grooves.
